(19) United States
(12) Patent Application Publication
(10) Pub. No.: US 2013/0001378 A1
(43) Pub. Date: Jan. 3, 2013

(54) SUPPORTING APPARATUS FOR ELECTRONIC DEVICE

(75) Inventors: YUN-LUNG CHEN, Tu-Cheng (TW); CHUNG CHAI, Tu-Cheng (TW); DA-LONG SUN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/439,940

(22) Filed: Apr. 5, 2012

(30) Foreign Application Priority Data
Jun. 28, 2011 (CN) 201110176811.3

(51) Int. Cl. H05K 7/16

(52) U.S. Cl. 248/121

(57) ABSTRACT

A supporting assembly for an electronic device, includes a mounting piece and a stand. The mounting piece is mounted on the electronic device. The mounting piece includes a connection piece. The connection piece defines a pivot hole. A positioning hole is defined in the connection piece. The stand includes a shaft. A positioning member is secured on the shaft and adapted to rotate together with the shaft. The positioning member includes a plurality of positioning bosses. The shaft is inserted in the pivot hole and rotatable in the pivot hole. Different positioning boss of the plurality of positioning bosses is adapted to be positioned in the positioning holes to hold the stand in different directions relative to the mounting piece.

### BACKGROUND

1. Technical Field

The present disclosure relates to a supporting apparatus, more particularly, to a supporting apparatus for supporting an electronic device.

2. Description of Related Art

Electronic devices, such as monitors, tablet computers, are often supported by a supporting assembly to stand on a desk for conveniently showing contents therein. However, conventional supporting assemblies often have complex structures and may include many components to assemble.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of a supporting assembly of an embodiment and an electronic device.

FIG. 2 is another exploded and isometric view of the supporting assembly of FIG. 1.

FIG. 3 is an assembled view of the supporting assembly of FIG. 2.

FIG. 4 is an assembled view of the supporting assembly and the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

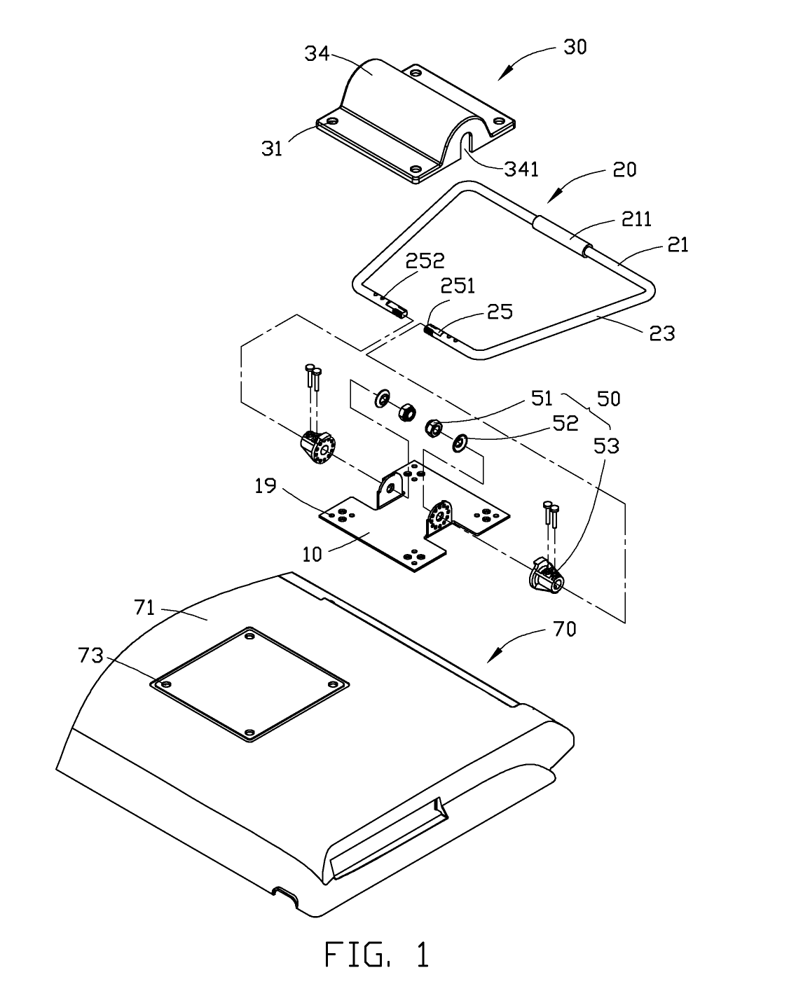

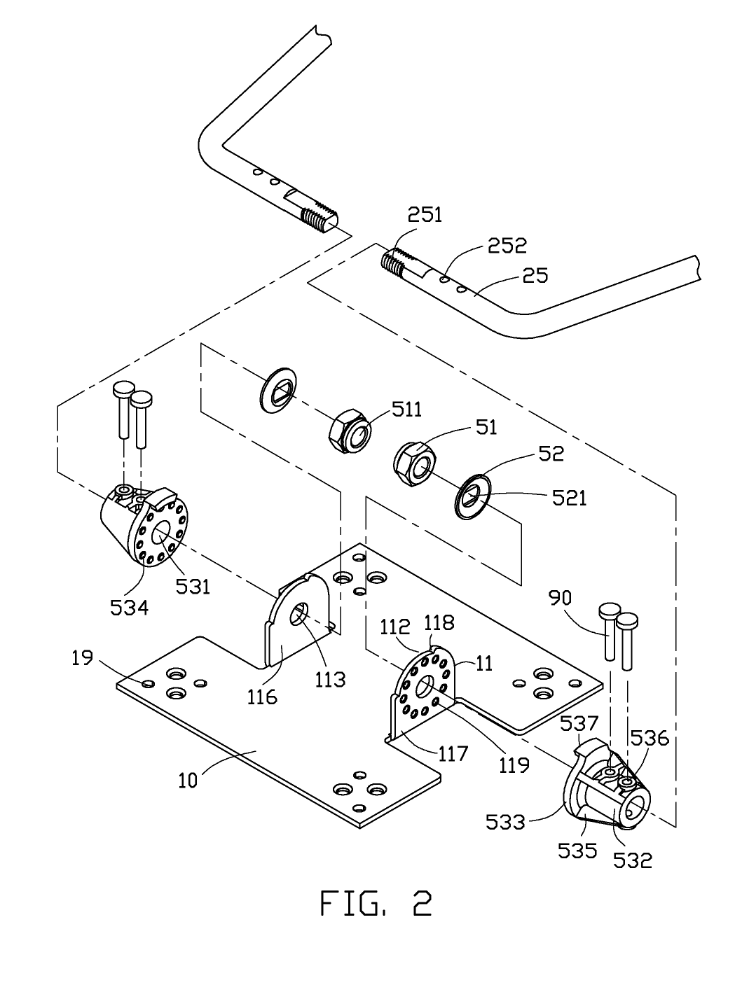

Referring to FIGS. 1 and 2, a support assembly in accordance with an embodiment, is used to support an electronic device 70. The support assembly includes a mounting piece 10, a stand 20, a cover 30, and two pivot assemblies 50. In one embodiment, the electronic device 70 is a monitor.

The mounting piece 10 is generally a square piece. Each of four corners of the mounting piece 10 defines a first mounting hole 19. A pair of connection pieces 11 is uprightly located on the mounting piece 10. Each of the pair of connection pieces 11 includes a first side 117 and a second side 116. A pivot hole 113 is in each of the pair of connection pieces 11. Two second sides 116 of the pair of connection pieces 11 face each other. A recess 112 is defined in a top peripheral portion of corresponding one of the pair of connection pieces 11. Each side of the recess 112 forms a barrier side 118. A plurality of positioning holes 119 are defined in the first side 117. The plurality of positioning holes 119 form in a circle and surrounds the pivot hole 113.

Each of the two pivot assemblies 50 includes a fastener 51, a gasket 52, and a positioning member 53. The fastener 51 defines a fixing hole 511. The positioning member 53 includes a main body 532 and a positioning piece 533 connected to one end of the main body 532. The positioning piece 533 forms a restricting piece 537 on a peripheral portion thereof. A plurality of positioning bosses 534 is protruded on the positioning piece 533. Each of the plurality of positioning bosses 534 can be elastically deformed. A plurality of ribs 535 is connected between the main body 532 and the positioning piece 533. The positioning member 53 defines a first through hole 531 which extends through the main body 532 and the positioning piece 533 in a first direction. The plurality of positioning bosses 534 surrounds the first through hole 531. A pair of first securing holes 536 is defined in the main body 532 in a second direction which is substantially perpendicular to the first direction. The pair of first securing holes 536 interconnect to the first through hole 531. The gasket 52 defines a double-D shaped second through hole 521.

The stand 20 is formed by a bent rod. The stand 20 includes a base 21. A skidproof pad 211 is set around the stand 20. Opposite ends of the base 21 extend obliquely to form a pair of supporting arms 23. Free ends of the pair of supporting arms 23 extend towards each other to form a pair of shafts 25. The pair of shafts 25 are parallel to the base 21. A distal end of each of the pair of shafts 25 is a fixing portion 251. A cross section of the fixing portion 251 is double-D shaped corresponding to the first through hole 531 and second through hole 521. A plurality of screw threads is formed on the fixing portion 251. Each of the pair of shafts 25 defines a pair of second securing holes 252 corresponding to the pair of first securing holes 536 of the positioning member 53.

Each of four corners of the cover 30 defines a second mounting hole 31. A central portion of the cover 30 is protruded to form a receiving portion 34. A receiving space 341 is defined in the receiving portion 34.

The electronic device 70 includes a rear plate 71. The rear plate 71 defines four third mounting holes 73.

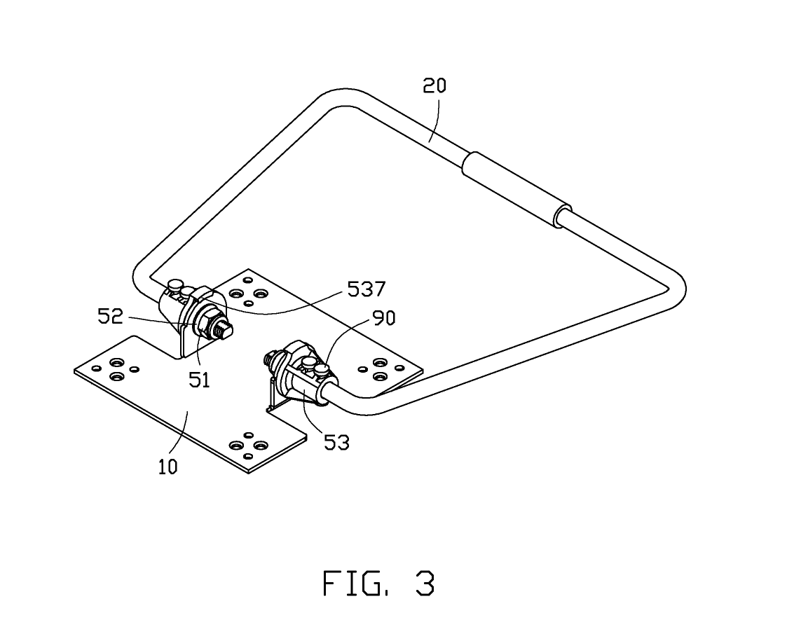

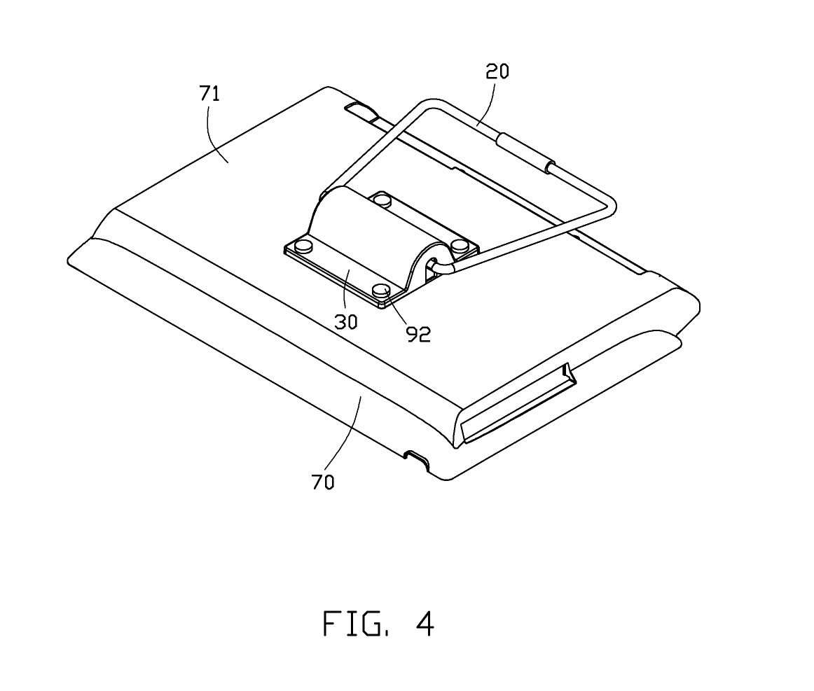

Referring to FIGS. 1 to 4, in assembly, the gasket 52 is placed on the second side 116 of each of the pair of connection pieces 11. The second through hole 521 is aligned to the pivot hole 113. The restricting piece 537 of the positioning member 53 is received in the recess 112 of each of the pair of connection pieces 11. The positioning piece 533 abuts the first side 117 of each of the pair of connection pieces 11. The plurality of positioning bosses 534 is positioned in the plurality of positioning holes 119. At this position, the first through hole 531 is aligned to the pivot hole 113.

The fixing portion 251 of each of the pair of shafts 25 is in turn inserted in the first through hole 531, the pivot hole 113, and the second through hole 521. Because shaped of the second through hole 521 and the cross section of the fixing portion 251 are double-D shape, the gasket 52 can rotate together with the pair of shafts 25. Each of the pair of shafts 25 is rotated to align the pair of second securing holes 252 with the pair of first securing holes 536. A pair of pins 90 are inserted in the pair of second securing holes 252 and the pair of first securing holes 536 to mount the positioning member 53 on each of the pair of shafts 25. Therefore, the positioning member 53 can rotate together with each of the pair of shafts 25. The fixing portion 251 is then fixed in the fixing hole 511 of the fastener 51 to mount the two pivot assemblies 50 and the stand 20 on the mounting piece 10. The gasket 52 is firmly contacted the second side 116. The positioning member 53 is contacted the first side 117. When each of the pair of shafts 25 rotates in the pivot hole 113, the plurality of positioning bosses 534 can be elastically deformed to escape from one of the plurality of positioning holes 119 and then be positioned in another one of the plurality of positioning holes 119 to locate the stand 20 in different positions. Further, each of the pair of shafts 25 is rotatable until one of the barrier side 118 abuts the restricting piece 537.

The pair of shafts 25 and the pair of connection pieces 11 are placed in the receiving space 341 of the cover 30. The mounting piece 10 is placed on the rear plate 71 of the electronic device 70. The first mounting holes 19 and the second mounting holes 31 are aligned to the third mounting holes 73. A plurality of screws 92 is secured in the first mounting holes 19, the second mounting holes 31, and the third mounting holes 73. So, the support assembly is pivotally mounted on the electronic device 70.

In use, the base 21 of the stand 20 is located on a desk. The skidproof pad 211 can prevent the base 21 from sliding on the desk. The pair of shafts 25 can rotate relative to the electronic device 70 to adjust an angle of the electronic device. Each of the plurality of positioning bosses 534 is positioned in a different one of the plurality of positioning holes 119 to hold the electronic device 70 in different inclined positions. Furthermore, barrier sides 118 abut the restricting piece 537 to prevent the stand 20 from rotating unduly.

In the embodiment, the shaped of the second through hole 521, and the cross section of the fixing portion 251 can be other non-circle shapes, as long as the fixing portion 251 and the gasket 52 can rotate together.

In an alternative embodiment, the plurality of positioning bosses 534 can be located on each of the pair of connection pieces 11, and the plurality of positioning holes 119 can be defined in the positioning member 53. If the plurality of positioning holes 119 are defined in the positioning member 53, the plurality of positioning holes 119 surround the first through hole 531.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A supporting assembly for an electronic device, comprising:
a mounting piece mounted on the electronic device, the mounting piece comprising a connection piece, the connection piece defining a pivot hole and a positioning hole;
a stand comprising a shaft; and
a positioning member secured on the shaft and adapted to rotate together with the shaft, the positioning member comprising a plurality of positioning bosses, the shaft being inserted into the pivot hole and rotatable in the pivot hole, and different one of the plurality of positioning bosses is adapted to be positioned in the positioning hole to hold the stand in different positions relative to the mounting piece.

2. The supporting assembly of claim 1, wherein the positioning member comprises a restricting piece, the connection piece defines a recess configure to receive the restricting piece therein, and the recess defines two barrier sides, and the shaft is rotatable until the restricting piece abuts one of the two barrier sides.

3. The supporting assembly of claim 2, wherein the recess is defined in a peripheral portion of the connection piece.

4. The supporting assembly of claim 1, wherein the positioning member defines a first through hole extending in a first direction, the shaft is inserted in the first through hole, and the plurality of positioning bosses surround the first through hole.

5. The supporting assembly of claim 4, wherein the plurality of positioning bosses are arranged in a substantially circle line.

6. The supporting assembly of claim 4, wherein the positioning member defines a first securing hole extending in a second direction, the second direction is perpendicular to the first direction, the shaft defines a second securing hole, a pin is inserted into the first securing hole and a second securing hole.

7. The supporting assembly of claim 1, wherein the positioning member comprises a positioning piece, the plurality of positioning bosses are located on the positioning piece, and a plurality of ribs are connected to the positioning piece.

8. The supporting assembly of claim 1, wherein the stand comprises a base, one end of the base extends obliquely to form a supporting arm, the supporting arm extends to form the shaft, and the shaft is parallel to the base.

9. The supporting assembly of claim 1, further comprising a gasket, the connection piece comprises a first side and a second side opposite to the first side, the positioning member contacts the first side, and the gasket contacts to the second side.

10. The supporting assembly of claim 9, wherein a shape of a cross section of the shaft is non-circular, the gasket defines a second non-circle hole, the shaft is inserted into the second non-circle hole to secure the gasket on the shaft.

11. A support assembly, comprising:
a mounting piece mounted on the electronic device, the mounting piece comprising a connection piece, the connection piece defining a pivot hole;
a stand comprising a shaft;
a positioning member secured on the shaft and adapted to rotate together with the shaft;
a plurality of positioning holes defined in one of the connection piece and the positioning member; and
a positioning boss formed on the other one of the connection piece and the positioning member;
wherein the shaft is adapted to inserted in the pivot hole and rotatable in the pivot hole, and the positioning boss is adapted to be positioned in different positioning holes of the plurality of positioning holes to hold the stand in different directions relative to the mounting piece.

12. The supporting assembly of claim 11, wherein the positioning member comprises a restricting piece, the connection piece defines a recess configured to receive the restricting piece therein, the recess comprises two barrier sides, and the shaft rotates until the restricting piece abuts one of the two barrier sides.

13. The supporting assembly of claim 12, wherein the recess is defined in a peripheral portion of the connection piece.

14. The supporting assembly of claim 11, wherein the positioning member defines a first through hole extending in a first direction, the shaft is inserted in the first through hole, and the plurality of positioning holes surround the first through hole if the plurality of positioning holes are defined in the positioning member.

15. The supporting assembly of claim 14, wherein the plurality of positioning holes are formed along a circle line.

16. The supporting assembly of claim 14, wherein the positioning member defines a first securing hole extending in a second direction, the second direction is perpendicular to the first direction, the shaft defines a second securing hole, a pin is inserted in the first securing hole and a second securing hole.

17. The supporting assembly of claim 11, wherein the stand comprises a base, one end of the base extends obliquely to form a supporting arm, the supporting arm extends to form the shaft, and the shaft is parallel to the base.

18. The supporting assembly of claim 11, further comprising a gasket, the connection piece comprises a first side and a second side opposite to the first side, the positioning member contacts the first side, and the gasket contacts to the second side.

19. The supporting assembly of claim 18, wherein a shape of a cross section of the shaft is non-circular, the gasket defines a second non-circle hole, the shaft is inserted in the second non-circle hole to secure the gasket on the shaft.
